(19) United States
(12) Patent Application Publication
(10) Pub. No.: US 2026/0159943 A1
(43) Pub. Date: Jun. 11, 2026

(54) PROCESSING APPARATUS, LITHOGRAPHY APPARATUS, REPAIRING METHOD, AND ARTICLE MANUFACTURING METHOD

(71) Applicant: CANON KABUSHIKI KAISHA, Tokyo (JP)

(72) Inventors: TOSHINAO TATSUNO, Kanagawa (JP); SHINJI FUKUI, Tochigi (JP); KOHEI IMOTO, Saitama (JP)

(21) Appl. No.: 19/182,080

(22) Filed: Apr. 17, 2025

(30) Foreign Application Priority Data
Apr. 24, 2024 (JP) 2024-070807

(51) Int. Cl. C23C 16/27; C23C 16/01; C23C 16/455; C23C 16/52

(52) U.S. Cl. CPC C23C 16/276; C23C 16/01; C23C 16/45536; C23C 16/52

(57) ABSTRACT

A processing apparatus for forming a diamond-like carbon film on a surface of a substrate support member, includes a head having an ejection hole configured to eject a raw material for forming the diamond-like carbon film, a driving mechanism configured to adjust a relative position between the substrate support member and the head, and a controller configured to control the driving mechanism so as to form the diamond-like carbon film at a target position of the substrate support member.

### BACKGROUND OF THE INVENTION

### Field of the Invention

The present invention relates to a processing apparatus, a lithography apparatus, a repairing method, and an article manufacturing method.

### Description of the Related Art

If a substrate chuck is repeatedly used in a semiconductor manufacturing process and the like, the substrate chuck is partially worn, thereby making it impossible to support a substrate in a flat state. Therefore, for example, in an exposure apparatus that transfers the pattern of an original to a substrate, a focusing error may occur and overlay accuracy may degrade. In addition, in an imprint apparatus, a thickness error of a pattern to be formed or the like may occur.

Japanese Patent Laid-Open No. 2020-24451 describes a method of repairing an object holder having a worn bar. In this repairing method, the worn bar is reconstructed to the original shape and/or height by sintering powder particles by laser sintering.

However, as described in Japanese Patent Laid-Open No. 2020-24451, in the method of sintering powder particles by laser sintering, a bar having a rough upper surface is formed, and thus it is necessary to polish the upper surface of the bar so as to obtain the bar having a flat upper surface.

### SUMMARY OF THE INVENTION

The present invention provides a technique advantageous in efficiently repairing the surface of a substrate support member.

One of aspects of the present invention provides a processing apparatus for forming a diamond-like carbon film on a surface of a substrate support member, comprising: a head having an ejection hole configured to eject a raw material for forming the diamond-like carbon film; a driving mechanism configured to adjust a relative position between the substrate support member and the head; and a controller configured to control the driving mechanism so as to form the diamond-like carbon film at a target position of the substrate support member.

Further features of the present invention will become apparent from the following description of exemplary embodiments with reference to the attached drawings.

### BRIEF DESCRIPTION OF THE DRAWINGS

FIG. 1 is a view showing the arrangement of a processing apparatus according to an embodiment;

FIGS. 2A to 2C are views for explaining an example of the arrangement of a head;

FIGS. 3A and 3B are views for explaining a method of measuring the shape of the surface of a substrate chuck;

FIGS. 4A to 4D are views for explaining a worn protrusion of the substrate chuck and repair of it;

FIG. 5 is a flowchart for explaining a method of repairing the substrate chuck;

FIGS. 6A and 6B are views for explaining a method of removing a DLC film;

FIG. 7 is a view showing the first arrangement example of a lithography apparatus incorporating the processing apparatus;

FIG. 8 is a flowchart illustrating an example of the operation of the lithography apparatus incorporating the processing apparatus;

FIG. 9 is a view showing the second arrangement example of the lithography apparatus incorporating the processing apparatus;

FIG. 10 is a view showing the third arrangement example of the lithography apparatus incorporating the processing apparatus; and

FIG. 11 is a view showing the fourth arrangement example of the lithography apparatus incorporating the processing apparatus.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

FIG. 1 shows the arrangement of a processing apparatus 100 according to an embodiment. The processing apparatus 100 can be formed as an apparatus that forms a diamond-like carbon film (to be referred to as a DLC film hereinafter) on the surface of a substrate chuck 110 serving as a substrate support member. The processing apparatus 100 can have a side surface of a repairing apparatus that repairs the substrate chuck 110.

The substrate chuck 110 can be incorporated in, for example, a lithography apparatus. For example, the substrate chuck 110 can be configured to chuck a substrate by a vacuum suction force or an electrostatic force. In an example, the substrate is a semiconductor wafer. The substrate may have one or a plurality of layers on the semiconductor wafer. The lithography apparatus is generally a pattern forming apparatus for forming a pattern on the substrate. More specifically, the lithography apparatus can be, for example, an exposure apparatus that exposes a substrate (photoresist) by projecting the pattern of an original to the substrate applied with the photoresist. A latent image pattern is formed on the exposed photoresist, and is converted into a physical pattern via a developing step. Alternatively, the lithography apparatus can be an imprint apparatus that transfers the pattern of a mold to a curable composition by bringing the mold as an original into contact with the curable composition arranged on a substrate and then curing the curable composition. Alternatively, the lithography apparatus can be a drawing apparatus that draws a pattern on a substrate applied with a photoresist by a charged particle beam (for example, an electron beam).

The substrate chuck 110 can be formed as a pin chuck including a plurality of protrusions (pins) 111, as shown in FIG. 1. In the processing apparatus 100, when the substrate chuck 110 holds a substrate, particles may be sandwiched between the surface of the substrate chuck 110 and the substrate. In this case, the surface of the substrate may be deformed locally. To prevent this, the pin chuck including the plurality of protrusions 111 can be adopted. By providing the plurality of protrusions 111, a contact area between the substrate chuck 110 and the substrate becomes small, thereby lowering the probability that particles are sandwiched between the surface of the substrate chuck 110 and the substrate. An example in which the substrate chuck 110 includes the plurality of protrusions 111 will be described below.

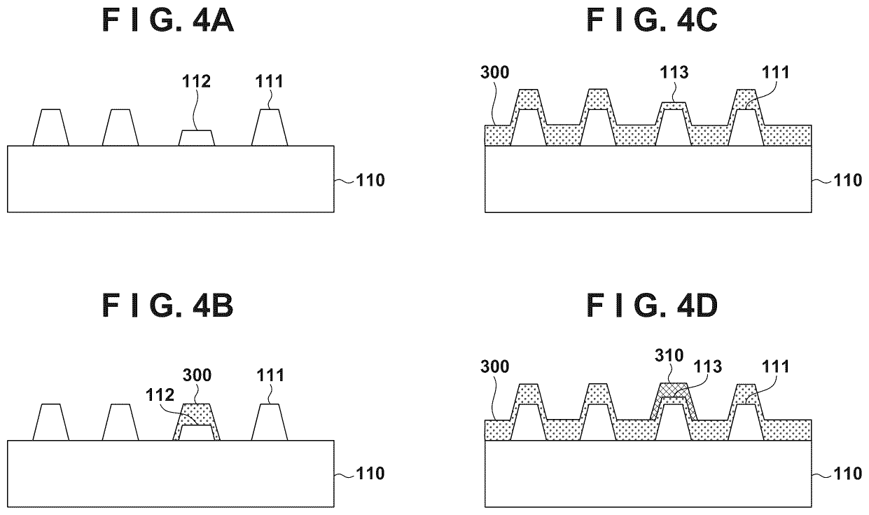

The substrate chuck 110 can have a DLC film on its surface. As exemplified in FIG. 4C, in the substrate chuck 110 having a DLC film 300 on its surface, only the DLC film 300 of a protrusion 113 may be worn. In this case, as exemplified in FIG. 4D, a DLC film 310 can be newly formed on the protrusion 113 in which only the DLC film 300 has been worn. In this example, since the DLC film 310 is formed on the DLC film 300, the adhesion or bonding force of the DLC film 310 with respect to the worn protrusion 113 can be improved.

Next, the processing apparatus 100 will be described. The processing apparatus 100 can include, for example, a head 130 having an ejection hole 131 that ejects a raw material (raw material gas) for forming the DLC film, and a driving mechanism 120 configured to adjust the relative position between the substrate chuck 110 and the head 130. The driving mechanism 120 can include, for example, a stage 122 that holds the substrate chuck 110, and a positioning mechanism 124 that positions the stage 122. The positioning mechanism 124 can include, for example, an actuator such as a motor. The processing apparatus 100 can include a controller 170 that controls the driving mechanism 120 so as to form the DLC film at a target position on the entire surface of the substrate chuck 110. The controller 170 can be formed by, for example, a PLD (the abbreviation of Programmable Logic Device) such as an FPGA (the abbreviation of Field Programmable Gate Array), an ASIC (the abbreviation of Application Specific Integrated Circuit), a general-purpose or dedicated computer incorporating a program, or a combination of some or all of these.

Furthermore, the processing apparatus 100 can include a raw material supply path 142 that supplies, to the head 130, the raw material for forming the DLC film. The raw material supply path 142 may be provided with a flow rate adjustor 140 that adjusts the flow rate of the raw material supplied to the head 130. The flow rate adjustor 140 may be, for example, a mass flow controller. The controller 170 can control the flow rate adjustor 140 to adjust the flow rate of the raw material supplied to the head 130. In addition, the processing apparatus 100 can include a driving power supply 160 that supplies, to the head 130, a driving voltage V for generating a plasma (for example, an atmospheric pressure plasma). The driving voltage V is supplied to the head 130 via a voltage supply line 162. The driving power supply 160 can include, for example, a pulse generator that supplies a pulse voltage as the driving voltage V to the head 130. The controller 170 can supply, to the driving power supply 160, a parameter value for controlling the driving voltage (for example, a waveform) supplied to the head 130. The stage 122 can be grounded.

In an example, the controller 170 can control the driving mechanism 120 so that the ejection hole 131 of the head 130 faces the target position on the entire surface of the substrate chuck 110 (substrate support member). Next, the controller 170 can control the driving power supply 160 so as to apply the driving voltage V between the stage 122 and the head 130 in a state in which the raw material is ejected from the ejection hole 131 of the head 130 at a set flow rate. Thus, for example, under an atmospheric pressure, a plasma for forming the DLC film can be generated, thereby forming the DLC film at the target position on the entire surface of the substrate chuck 110 (substrate support member).

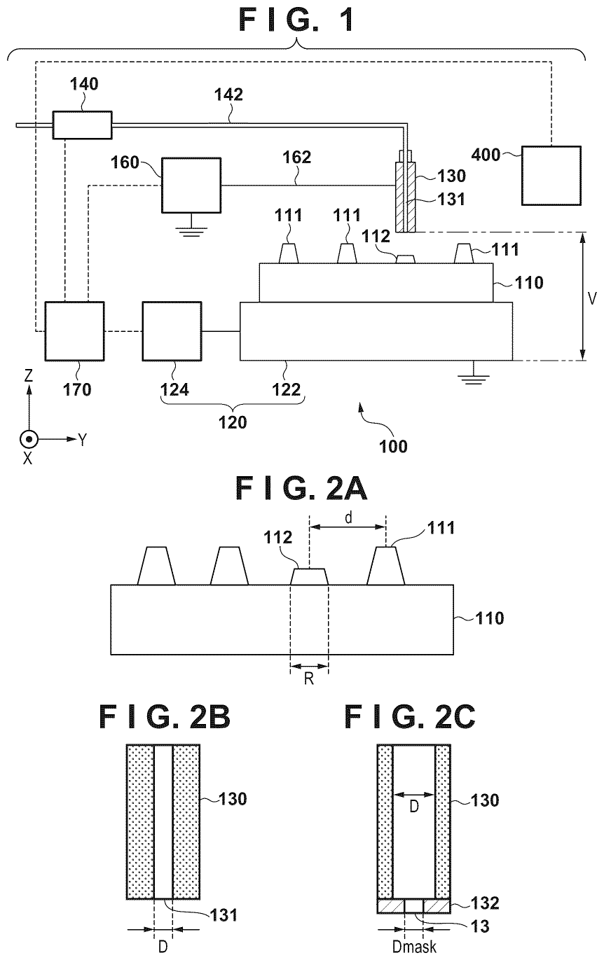

As exemplified in FIG. 2B, the head 130 can include a cylindrical member made of a conductor such as a metal. The ejection hole 131 may be a through hole formed in the cylindrical member to have an inner diameter D, and communicates with the raw material supply path 142. The DLC film having a diameter close to the inner diameter D can be formed on the substrate chuck 110. Therefore, the inner diameter D of the ejection hole 131 of the head 130 is preferably smaller than the diameter of a worn protrusion 112 of the substrate chuck 110. Consider a case where the substrate chuck 110 includes the plurality of protrusions 111 and the worn protrusion 112, as exemplified in FIG. 2A. To prevent the DLC film from being formed simultaneously on the worn protrusion 112 and its adjacent protrusion 111, D≤d−R is preferably satisfied where d represents a center-to-center distance between the worn protrusion 112 and its adjacent protrusion 111. In the arrangement exemplified in FIG. 2B, D=d−R preferably holds in terms of productivity. Alternatively, as exemplified in FIG. 2C, the diameter of the outlet of the ejection hole 131 may be defined by the mask 132 having a through hole with a diameter Dmask. In this case, Dmask≤d−R is preferably satisfied. In the arrangement exemplified in FIG. 2C, Dmask=d−R preferably holds in terms of productivity.

A member forming the raw material supply path 142, for example, a supply tube can be made of an insulator to prevent a voltage supplied to the head 130 through the voltage supply line 162 from being supplied through the raw material supply path 142. Alternatively, the head 130 and the raw material supply path 142 may be insulated by an insulating member. A ground terminal of the driving power supply 160 is grounded.

The raw material (raw material gas) supplied to the head 130 through the raw material supply path 142 can be, for example, a hydrocarbon gas such as methane, ethylene, propane, or toluene. To increase the hardness of the DLC film, the raw material (raw material gas) for forming the DLC film is preferably methane. To increase the hardness of the DLC film, a method of generating a plasma by glow discharge is better than a method of generating a plasma by arc discharge. If a plasma is generated under an atmospheric pressure, it is easy to transition to arc discharge. To maintain glow discharge, it is preferable to mix helium gas in the raw material gas. To generate a plasma by glow discharge, a voltage pulse as the driving voltage V preferably has a short pulse width, a high voltage, and a high frequency. For example, it is preferable that the pulse width falls within the range of 400 nsec to 800 nsec, the voltage value falls within the range of 1 kV to 3 kV, and the frequency falls within the range of 3 kHz to 5 kHz.

In the example shown in FIG. 1, the driving mechanism 120 configured to adjust the relative position between the substrate chuck 110 (substrate support member) and the head 130 is configured to move the substrate chuck 110. However, the driving mechanism 120 may be configured to move the head 130 or move both the substrate chuck 110 and the head 130. In processing of forming the DLC film, the head 130 and the stage 122 (and the substrate chuck 110) can be arranged in a local exhaust ventilation in order to prevent an unreacted raw material (raw material gas) from being discharged to the external space of the processing apparatus 100.

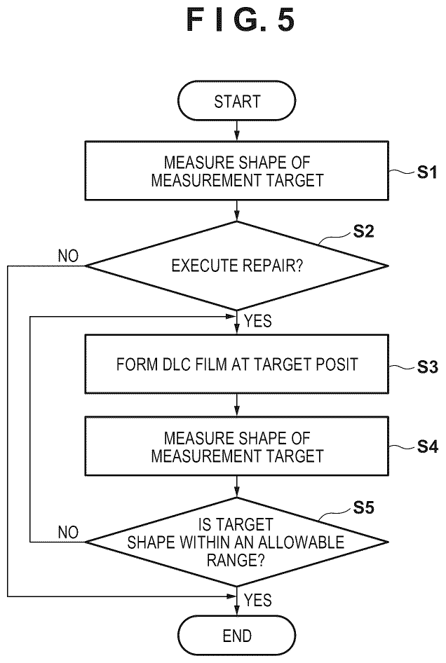

A practical example of a repairing method of repairing the worn protrusion 112 of the substrate chuck 110 in the processing apparatus 100 to have a target shape will be described below with reference to FIGS. 1 and 3A to 6B. FIG. 5 exemplifies the procedure of the repairing method.

In step S1, the controller 170 measures the shape of a measurement target. The measurement target may be the surface of the substrate chuck 110 (a substrate holding surface including the plurality of protrusions 111), or the surface of a substrate 200 held by the substrate chuck 110. In the latter case, if the plurality of protrusions 111 of the substrate chuck 110 include the worn protrusion 112, a recess and distortion caused by the protrusion 112 may be generated on the surface of the substrate 200. A method of measuring the shape of the surface of the substrate 200 held by the substrate chuck 110 is simpler than a method of measuring the shape of the surface of the substrate chuck 110, and is advantageous in decreasing error factors. Thus, an example of adopting the method of measuring the shape of the surface of the substrate 200 held by the substrate chuck 110 will be described below.

The substrate 200 may be a material substrate for manufacturing a device by the lithography apparatus including the substrate chuck 110, or a measurement substrate. A shape of interest may be unevenness of the surface of the substrate 200, that is, the height distribution of the surface of the substrate 200 (the deformation amount in the out-of-plane direction of the substrate 200), or distortion in a direction along the surface of the substrate (the deformation amount in the in-plane direction of the substrate 200). The distortion of the substrate can be measured by, for example, measuring a pattern arranged on the surface of the substrate 200.

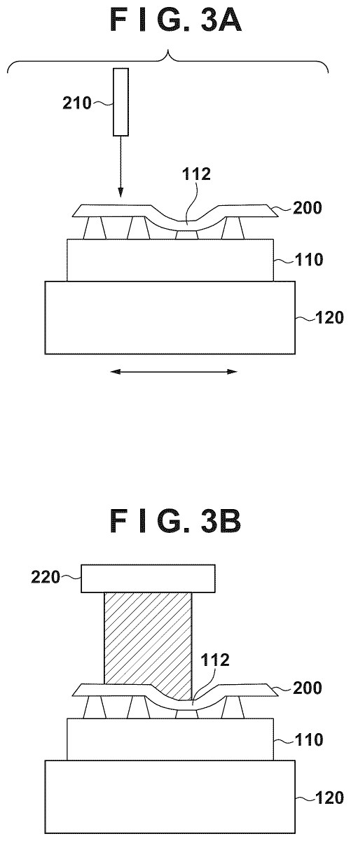

To measure the shape of the surface of the substrate 200, for example, a displacement measuring device 210 that measures a local displacement can be used, as schematically shown in FIG. 3A. Alternatively, to measure the shape of the surface of the substrate 200, a plane displacement measuring device 220 that collectively measures unevenness in a wide range may be used, as schematically shown in FIG. 3B. Alternatively, another measuring device may be used.

Examples of the displacement measuring device 210 that measures a local displacement can be a range interferometer and a trigonometric displacement meter. For example, it is possible to measure the height distribution of the surface of the substrate 200 (the deformation amount in the out-of-plane direction of the substrate 200) by measuring the height of the substrate 200 or the substrate chuck 110 by the displacement measuring device 210 while horizontally driving the stage 122. Instead of moving the stage 122, the displacement measuring device 210 may be moved or both the stage 122 and the displacement measuring device 210 may be moved.

An example of the plane displacement measuring device 220 that collectively measures unevenness in a wide range can be a plane interferometer. However, if the plane interferometer with a measurement range that can measure the entire surface of the substrate 200 is adopted, cost is increased, and thus the plane displacement measuring device that measures a measurement range smaller than the entire surface of the substrate chuck 110, as schematically shown in FIG. 3B, may be used. In this case, measurement is performed while moving at least one of the stage 122 and the plane displacement measuring device 220.

In general, the method of relatively driving the displacement measuring device 210 and the substrate 200 as schematically shown in FIG. 3A is affected by the running error (a deviation from a plane caused by relative driving) of the displacement measuring device 210 and/or the substrate chuck 110. Therefore, in order to improve measurement accuracy, measurement by the plane displacement measuring device that collectively measures a wide range can decrease the measurement error more.

The size of the range that is collectively measured by the plane displacement measuring device 220 is preferably a size including a shot region as the largest structural unit of the device manufactured in the substrate 200. In this case, since it is possible to collectively measure the shot region, the error caused by relative driving can be decreased. In addition, when the size of the range that is collectively measured is set slightly larger than the shot region, it is possible to obtain a shape measurement result with respect to measurement of the entire surface of the substrate 200 by performing stitching to match the overlap of displacement measurement with the adjacent shot region.

In step S2, based on the result obtained in step S1, that is, the output of the measuring device that measures the shape of the surface of the substrate chuck 110, the controller 170 determines whether to execute formation of the DLC film to repair the substrate chuck 110. If, for example, the depth of the recess of the surface of the substrate chuck 110 is larger than a threshold, the controller 170 can determine to perform deposition for repair. Alternatively, based on the transition of the depth of the recess, the controller 170 can determine to perform deposition for repair. Alternatively, based on the transition of the depth of the recess, the controller 170 may decide the date/time (to be referred to as the deposition date/time hereinafter) when deposition for repair is performed, and then perform deposition for repair when the timing arrives. If the deposition date/time is earlier than the next measurement date/time, deposition is performed on the deposition date/time. On the other hand, if the deposition date/time is later than the next measurement date/time, the deposition date/time may be modified based on the result of the next measurement.

In a case where the depth of the recess is larger than a predetermined criterion depth, or a case where the number of parts to be repaired is larger than a predetermined criterion number, an excessive repairing time is required. In this case, the controller 170 may determine to make no repair, and notify an operator of it using a display device and/or a notifier such as an alarm lamp.

In step S2, based on the measurement result (in other words, the output of the measuring device) of the shape of the measurement target measured in step S1, the controller 170 decides, as the target position where the DLC film is formed, a position where the worn protrusion 112 shown in FIG. 4A exists. As shown in FIG. 4B, the controller 170 executes processing of forming the DLC film 300 on the worn protrusion 112. More specifically, first, the controller 170 controls the driving mechanism 120 so that the head 130 is located above the worn protrusion 112. Next, the controller 170 controls the flow rate adjustor 140 so as to supply the raw material to the head 130 through the raw material supply path 142. This ejects the raw material from the ejection hole 131. Furthermore, the controller 170 controls the driving power supply 160 so as to supply the driving voltage V to the head 130. This generates a plasma near the ejection hole 131. The supply time of the driving voltage V is decided so as to form the DLC film of a target thickness on the worn protrusion 112, that is, at the target position (or the target region). When the supply of the driving voltage V for the decided supply time ends, the controller 170 controls the flow rate adjustor 140 to stop the supply of the raw material. Thus, the formation of the DLC film stops.

A method of deciding the supply time of the driving voltage V will now be described. In the processing apparatus 100, a substrate, such as a silicon wafer, whose refractive index is known or a substrate whose surface is partially masked is supported by the stage 122, and the DLC film is formed on the substrate. In a case where the DLC film is formed on the substrate whose refractive index is known, it is possible to measure the thickness of the DLC film by spectroscopic ellipsometry or the like. In a case where the DLC film is formed on the substrate whose surface is partially masked, it is possible to measure the thickness of the DLC film by removing the mask after the formation of the DLC film and measuring a step generated after the removal using a contact-type film thickness measuring system such as a step gauge. Based on the thickness of the formed DLC film and the time taken to form the DLC film (that is, the supply time of the driving voltage V), the forming rate R of the DLC film can be calculated. In this manner, the forming rate R of the DLC film is acquired in advance. The controller 170 can decide a supply time (film formation time) T of the driving voltage V based on the forming rate R and a height reduction amount ΔH as a difference between the height of the worn protrusion 112 and the height (or the target height) of the protrusion 111 that is not worn. Note that the height reduction amount ΔH appears as the depth of the recess caused by the worn protrusion 112 in a result of measuring the surface shape (height distribution) of the substrate 200 while supporting the substrate 200 by the substrate chuck 110. The height reduction amount ΔH may also be understood as the target thickness of the DLC film to be formed. More specifically, the controller 170 can decide the supply time T based on T=ΔH/R.

For example, by setting the distance between the head 130 and the substrate (substrate chuck 110) to 1 mm to 10 mm, methane is supplied at a flow rate of 0.05 to 0.2 L/min to the head 130 and helium is supplied at a flow rate of 2 to 8 L/min to the head 130. The driving voltage V is supplied to the head 130 under an atmospheric pressure with a pulse width of 400 nsec to 800 nsec, a voltage of 1 kV to 3 kV, and a pulse frequency of 3 kHz to 5 kHz. In an example, the forming rate R of the DLC film is 0.3 μm/min. In step S3, if the height reduction amount ΔH of the worn protrusion 112 is 0.6 μm and the forming rate R is 0.3 μm/min, the supply time (film formation time) T of the driving voltage V is 2 min by T=ΔH/R.

In step S4, the controller 170 measures the shape of the substrate 200 as the measurement target, similar to step S1. Next, in step S5, the controller 170 determines whether the difference between the shape of the substrate 200 and the target shape falls within an allowable range. If the difference falls outside the allowable range, the controller 170 re-executes steps S3 to S5. That is, the controller 170 repeatedly executes steps S3 to S5 until the difference between the shape of the substrate 200 and the target shape falls within the allowable range.

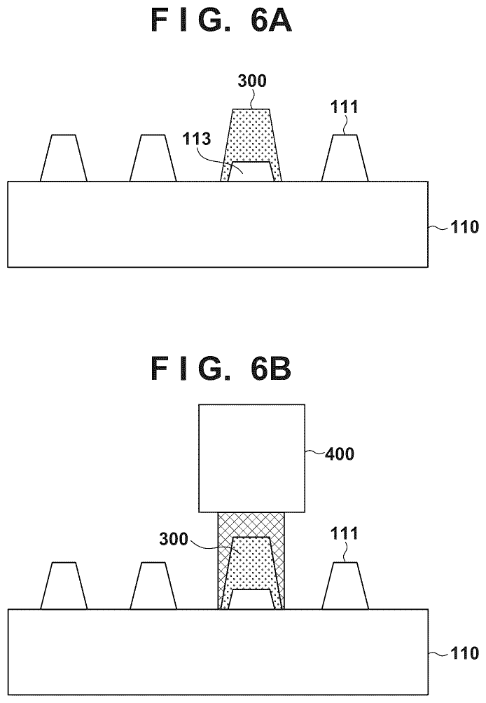

In this example, as schematically shown in FIG. 6A, the DLC film 300 may be formed excessively on the worn protrusion 113. In this case, as schematically shown in FIG. 6B, a remover 400 is used to remove at least a portion (removing target) of the DLC film 300, and the repairing method shown in FIG. 5 can be performed again thereafter, as needed. To remove the DLC film 300, the DLC film 300 is heated to a temperature of 400° C. or more. When the DLC film 300 is heated to a temperature of 400° C. or more, it is oxidized to carbon dioxide or carbon monoxide, and is then removed. The remover 400 can be configured to, for example, emit electromagnetic radiation such as a laser beam to the DLC film 300 to be removed in order to locally heat the substrate chuck 110. However, in a case where the protrusion 113 (DLC film 300) and the emission portion of the remover 400 can be arranged close to each other, the remover 400 may include an electromagnetic induction heater or a heater. The remover 400 may be configured to emit electromagnetic radiation that passes through the substrate 200 placed on the substrate chuck 110. In an example, in a case where the substrate 200 is a silicon wafer, the remover 400 can be configured to emit infrared rays that pass through silicon. In this case, it is possible to measure the shape of the substrate chuck 110 while the silicon wafer as the substrate 200 is placed on the substrate chuck 110. Therefore, it is possible to decrease the error caused by replacement of the substrate 200.

As shown in FIG. 1, the processing apparatus 100 may include the remover 400. In an example, a function of moving at least one of the substrate chuck 110 (stage 122) and the remover 400 is provided, and this function can be provided by, for example, the driving mechanism 120. This function may be provided by another driving mechanism. In a case where the remover 400 is configured to emit electromagnetic radiation such as a laser beam, the remover 400 may emit electromagnetic radiation to the target position on the substrate chuck 110 using a deflection device such as a galvano scanner.

As a method of removing the DLC film 300, an oxygen plasma or an argon plasma may be emitted to the DLC film 300. For example, an oxygen plasma or an argon plasma is generated by supplying oxygen or argon to the head 130 and supplying the driving voltage V (for example, the pulse voltage) from the driving power supply 160 to the head 130, thereby making it possible to remove the DLC film 300. As a method of removing the DLC film 300, a method by heating and an oxygen plasma or argon plasma may be used in combination.

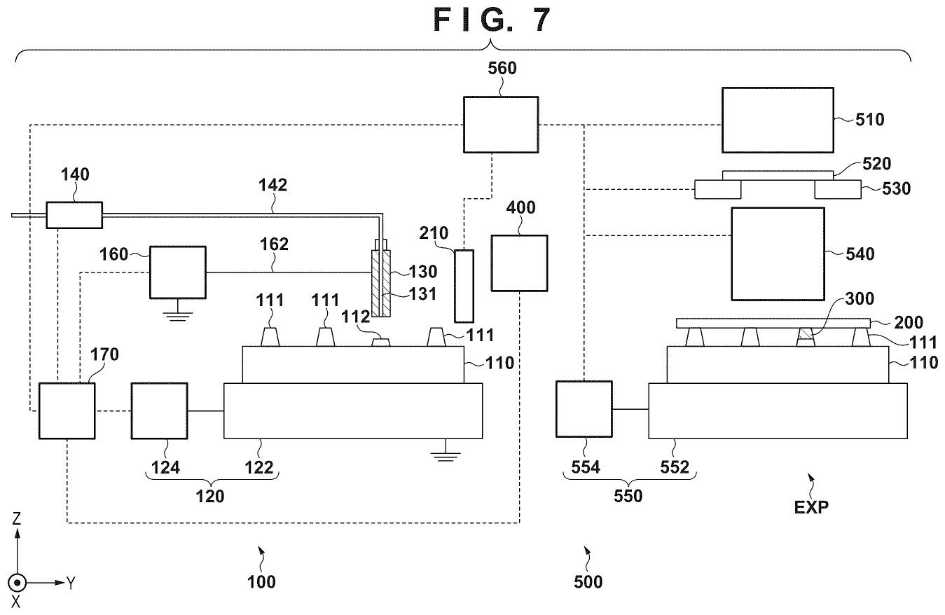

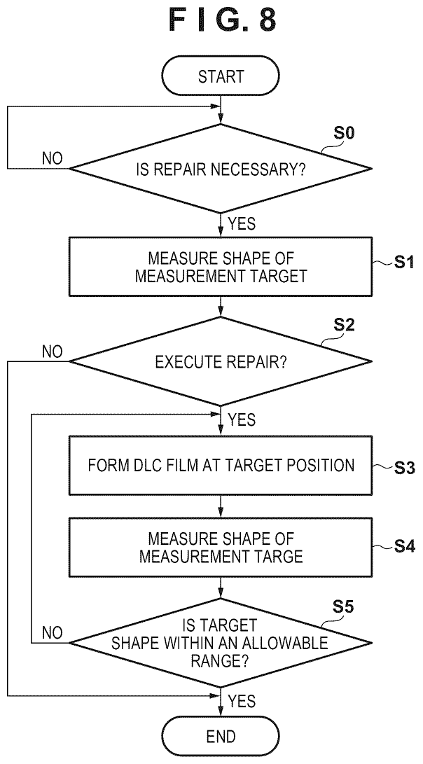

An exposure apparatus 500 incorporating the processing apparatus 100 will be described below as an example of a lithography apparatus incorporating the processing apparatus 100. FIG. 7 shows the first arrangement example of the exposure apparatus 500 incorporating the processing apparatus 100. FIG. 8 shows an example of the operation of the exposure apparatus 500. Processing shown in FIG. 8 is obtained by adding step S0 to the processing shown in FIG. 5. Step S0 can be executed by a main controller 560, and steps S1 to S5 can be executed by the controller 170 under the control of the main controller 560.

For example, step S0 may be executed in the background, activated by the operator, or activated by a program (software) such as a maintenance program. In step S0, the main controller 560 determines whether it is necessary to repair the substrate chuck 110. Based on, for example, the number of substrates processed after final maintenance of the substrate chuck 110, the operation time of the exposure apparatus 500, and the like, the main controller 560 can determine that it is necessary to repair the substrate chuck 110. Alternatively, if the frequency at which a focusing error occurs exceeds a predetermined frequency, the main controller 560 can determine that it is necessary to repair the substrate chuck 110. Alternatively, if the range (the difference between the maximum value and the minimum value) of a focus control amount for each of a plurality of shot regions of each substrate exceeds a predetermined range, the main controller 560 can determine that it is necessary to repair the substrate chuck 110. Alternatively, if step S0 is activated by the operator, the main controller 560 can determine that it is necessary to repair the substrate chuck 110. This is because the operator may suspect occurrence of wear in the substrate chuck 110 based on an inspection result of an inspection apparatus such as an overlay inspection apparatus. Alternatively, if step S0 is automatically activated in accordance with a plan created in advance, the main controller 560 can determine that it is necessary to repair the substrate chuck 110. If the main controller 560 determines that it is necessary to repair the substrate chuck 110, it causes the controller 170 to perform steps S1 to S5.

Steps S1 and S4 of measuring the shape of the measurement target and step S3 of forming the DLC film are conveniently performed in a state in which the substrate chuck 110 is held by a stage 552 of a substrate stage mechanism 550 for exposing the substrate 200. However, due to the arrangement constraints of the components of the exposure apparatus 500, there is a case where the head 130 and the like cannot be arranged within the movable range of the stage 552 (substrate chuck 110) of the substrate stage mechanism 550. In this case, a main body EXP of the exposure apparatus 500 and the processing apparatus 100 can be arranged apart from each other. The main body EXP and the processing apparatus 100 can be accommodated in different chambers. Note that the main body EXP is a portion that executes processing of exposing the substrate.

When repairing the substrate chuck 110, the substrate chuck 110 is detached from the stage 552 of the substrate stage mechanism 550, placed on the stage 122 of the processing apparatus 100, and held by the stage 122, and then steps S1 to S5 can be executed.

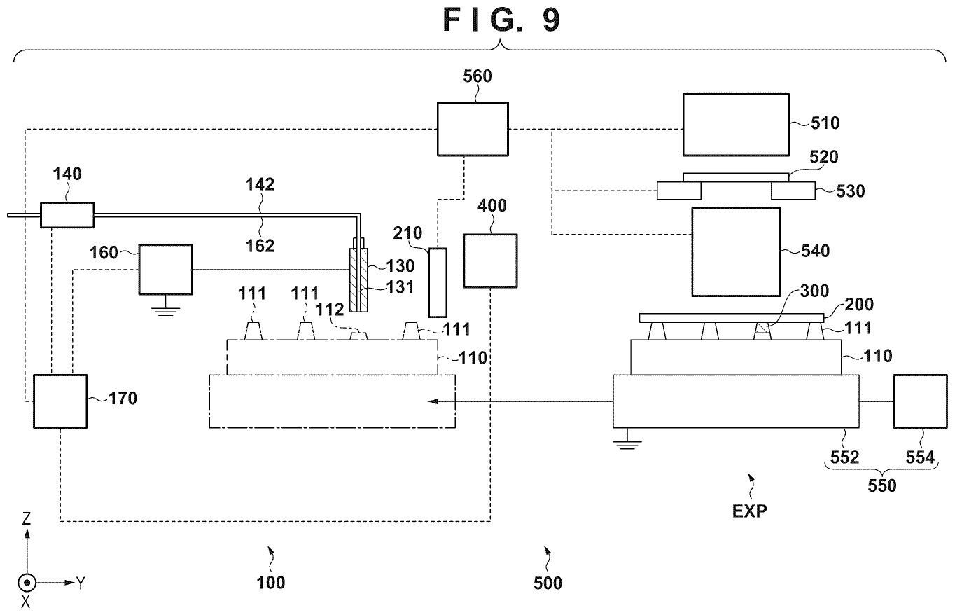

FIG. 9 shows the second arrangement example of the exposure apparatus 500 incorporating the processing apparatus 100. In the second arrangement example, the head 130 is arranged within the movable range of the stage 552 (substrate chuck 110) of the substrate stage mechanism 550. When performing steps S1 to S5, the stage 552 holding the substrate chuck 110 can be driven by a positioning mechanism 554 of the substrate stage mechanism 550 so that the target position of the substrate chuck 110 is arranged under the head 130 of the processing apparatus 100. If the driving stroke of the stage 552 (substrate chuck 110) by the positioning mechanism 554 is insufficient, a driving mechanism that drives the head 130 may be provided.

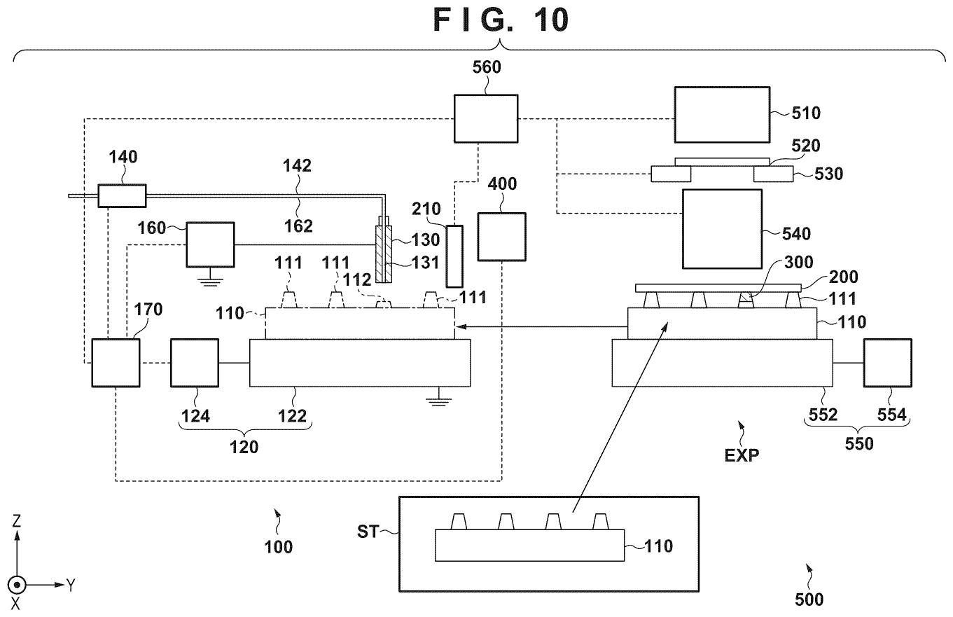

FIG. 10 shows the third arrangement example of the exposure apparatus 500 incorporating the processing apparatus 100. In the third arrangement example, the processing apparatus 100 includes the driving mechanism 120 and the main body EXP includes the substrate stage mechanism 550. During a period in which the substrate chuck 110 is repaired in the processing apparatus 100, another substrate chuck 110 can be attached to the substrate stage mechanism 550 of the main body EXP, and processing of exposing the substrate 200 can be performed. Another substrate chuck 110 for replacement can be stored in, for example, a stocker ST.

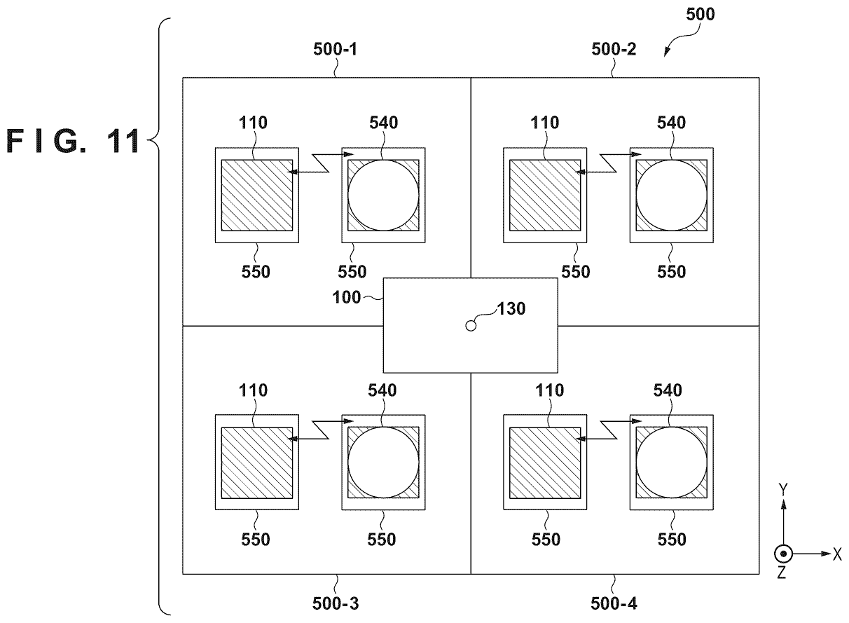

FIG. 11 shows the fourth arrangement example of the exposure apparatus 500 incorporating the processing apparatus 100. In the fourth arrangement example, the exposure apparatus 500 includes a plurality of exposure stations 500-1, 500-2, 500-3, and 500-4 and at least one processing apparatus 100. Therefore, the plurality of exposure stations 500-1, 500-2, 500-3, and 500-4 share the at least one processing apparatus 100. Each of the plurality of exposure stations 500-1, 500-2, 500-3, and 500-4 can have the same arrangement as that of the above-described main body EXP.

The arrangement of the main body EXP of the exposure apparatus 500 will exemplarily be described below. The main body EXP can be formed as a stepper that exposes the substrate 200 in a stationary state but may be formed as a scanner (scanning exposure apparatus) that exposes the substrate 200 while scanning it. The operation of the exposure apparatus 500 formed as a scanner will exemplarily be described below.

The main body EXP can include, for example, an illumination optical system 510, an original stage 530, a projection optical system 540, and the main controller 560. The substrate chuck 110 can be placed on the stage 552 of the substrate stage mechanism 550 and held by the stage 552. The substrate stage mechanism 550 can drive the stage 552 in at least the X direction, the Y direction, the Z direction, and the like. The main controller 560 can be formed by, for example, a PLD (the abbreviation of Programmable Logic Device) such as an FPGA (the abbreviation of Field Programmable Gate Array), an ASIC (the abbreviation of Application Specific Integrated Circuit), a general-purpose or dedicated computer incorporating a program, or a combination of some or all of these.

The illumination optical system 510 includes a light shielding member such as a masking blade, and can shape light emitted from a light source (not shown) into, for example, band-like or arcuate slit light long in the X direction and illuminate a portion of an original 520 with this slit light. The original 520 and the substrate 200 are held by the original stage 530 and the substrate chuck 110, respectively, and arranged at substantially optically conjugate positions (on the object plane and image plane of the projection optical system 540) via the projection optical system 540. The projection optical system 540 projects the pattern of the original 520 to each of a plurality of shot regions of the substrate 200 held by the substrate chuck 110, thereby exposing the plurality of shot regions. More specifically, the projection optical system 540 has a predetermined projection magnification (for example, ½ or ¼). Then, in exposure of each shot region, the original stage 530 and the substrate chuck 110 are relatively scanned in synchronism with each other in a direction (for example, the Y direction) orthogonal to the optical axis direction (Z direction) of the projection optical system 540 at a velocity ratio corresponding to the projection magnification of the projection optical system 540.

An article manufacturing method of manufacturing an article by the lithography apparatus incorporating the processing apparatus 100 will be described below. For example, the article manufacturing method is suitable for manufacturing an article, for example, a microdevice such as a semiconductor device or an element having a fine structure. The article manufacturing method according to an embodiment can include a pattern forming step of forming a pattern on a substrate using the above-described lithography apparatus (for example, an exposure apparatus, an imprint apparatus, a drawing apparatus, or the like), and a processing step of obtaining an article by processing the substrate having undergone the pattern forming step. The processing step includes, for example, developing, etching, oxidation, deposition, vapor deposition, doping, planarization, resist removal, dicing, bonding, and packaging.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-070807, filed Apr. 24, 2024 which is hereby incorporated by reference herein in its entirety.

What is claimed is:

1. A processing apparatus for forming a diamond-like carbon film on a surface of a substrate support member, comprising:
a head having an ejection hole configured to eject a raw material for forming the diamond-like carbon film;
a driving mechanism configured to adjust a relative position between the substrate support member and the head; and
a controller configured to control the driving mechanism so as to form the diamond-like carbon film at a target position of the substrate support member.

2. The apparatus according to claim 1, further comprising a driving power supply configured to supply, to the head, a driving voltage for generating a plasma,
wherein the controller controls the driving mechanism and the driving power supply.

3. The apparatus according to claim 2, further comprising a flow rate adjustor configured to adjust a flow rate of the raw material supplied to the head,
wherein the controller controls the driving mechanism, the driving power supply, and the flow rate adjustor.

4. The apparatus according to claim 3, wherein the controller adjusts the driving mechanism, the driving power supply, and the flow rate adjustor so as to form the diamond-like carbon film of a target thickness at the target position.

5. The apparatus according to claim 2, wherein the plasma is an atmospheric pressure plasma.

6. The apparatus according to claim 1, further comprising a measuring device configured to measure a shape of the surface of the substrate support member.

7. The apparatus according to claim 6, wherein
the measuring device measures a shape of a surface of a substrate held by the substrate support member, and
the controller decides the target position based on an output of the measuring device.

8. The apparatus according to claim 1, further comprising a remover configured to remove at least a portion of the diamond-like carbon film formed on the surface of the substrate support member.

9. The apparatus according to claim 8, wherein the remover heats a removing target of the diamond-like carbon film.

10. The apparatus according to claim 8, wherein the remover generates a plasma for removing a removing target of the diamond-like carbon film.

11. The apparatus according to claim 10, wherein the plasma for removing the removing target is one of an oxygen plasma and an argon plasma.

12. The apparatus according to claim 1, wherein a plasma for removing at least a portion of the diamond-like carbon film formed on the surface of the substrate support member is generated by supplying a predetermined gas to the head.

13. The apparatus according to claim 12, wherein the predetermined gas includes one of oxygen and argon.

14. A lithography apparatus for forming a pattern on a substrate held by a substrate support member, comprising:
a processing apparatus defined in claim 1, and controlled to repair the substrate support member.

15. The apparatus according to claim 14, further comprising a plurality of stations each configured to perform processing of forming the pattern on the substrate,
wherein the plurality of stations share the processing apparatus.

16. An article manufacturing method comprising:
forming a pattern on a substrate using a lithography apparatus defined in claim 14; and
obtaining an article by processing the substrate having undergone the forming.

17. A repairing method of repairing a substrate support member, comprising:
measuring a shape of a surface of the substrate support member; and
forming a diamond-like carbon film by a plasma at a target position decided based on the shape of the surface.

18. The method according to claim 17, wherein in the measuring, the shape of the surface of the substrate support member is measured by measuring a shape of a surface of a substrate held by the substrate support member.

19. The method according to claim 17, further comprising removing at least a portion of the diamond-like carbon film having an excessive thickness.

20. An article manufacturing method comprising:
forming a pattern on a substrate while holding the substrate by a substrate support member in a lithography apparatus;
obtaining an article by processing the substrate having undergone the forming; and
repairing the substrate support member by a repairing method defined in claim 17.
